(19) United States
(12) Patent Application Publication
(10) Pub. No.: US 2025/0038628 A1
(43) Pub. Date: Jan. 30, 2025

(54) INVERTER INCLUDING WIDE-BANDGAP SEMICONDUCTOR DEVICES IN A POWER TOOL

(71) Applicant: MILWAUKEE ELECTRIC TOOL CORPORATION, Brookfield, WI (US)

(72) Inventors: Donald J. Truettner, Waukesha, WI (US); Maxwell L. Merget, Whitefish Bay, WI (US); Douglas R. Fieldbinder, Greendale, WI (US)

(21) Appl. No.: 18/716,883

(22) PCT Filed: Dec. 8, 2022
(86) PCT No.: PCT/US2022/081154

§ 371 Date: Jun. 5, 2024

Related U.S. Application Data
(60) Provisional application No. 63/292,585, filed on Dec. 22, 2021.
(60) Provisional application No. 63/288,264, filed on Dec. 10, 2021.

(51) Int. Cl. H02K 11/33; B25F 5/00; H02K 7/14; H02M 7/00; H02M 7/483; H02M 7/5387

(52) U.S. Cl. CPC H02K 11/33; B25F 5/008; H02K 7/145; H02M 7/003; H02M 7/4837; H02M 7/5387

(57) ABSTRACT

A power tool includes a motor, a power source, and a printed circuit board (“PCB”) electrically connected to the motor and the power source. The PCB is mounted to the motor. The PCB includes a plurality of wide band gap semiconductor switches configured as an inverter for controlling power supplied by the power source to the motor.

### RELATED APPLICATIONS

This application claims the benefit of U.S. Provisional Patent Application No. 63/288,264, filed Dec. 10, 2021, and U.S. Provisional Patent Application 63/292,585, filed Dec. 22, 2021, the entire content of each of which is hereby incorporated by reference.

### FIELD

Embodiments described herein relate to an inverter included within an electrical device, such as a power tool.

### SUMMARY

Power tools described herein include a motor, a power source, and a printed circuit board (“PCB”) electrically connected to the motor and the power source. The PCB is mounted to the motor. The PCB includes a plurality of wide band gap semiconductor switches configured as an inverter for controlling power supplied by the power source to the motor.

In some aspects, the motor includes a frame, and the PCB is mounted directly to the frame.

In some aspects, the motor is configured to act as a heat sink for the inverter.

In some aspects, the power tool includes a heat sink, the PCB is mounted to the heat sink, and the heat sink is mounted to the motor.

In some aspects, the heat sink is air cooled.

In some aspects, the power tool includes input capacitors, and the input capacitors and the inverter are mounted on the same side of the PCB.

In some aspects, the power tool includes a heat plate connected to the motor.

In some aspects, the heat plate is connected to a heat pipe and the heat pipe is connected to a heat sink.

In some aspects, the motor, PCB, and the heat plate are housed in a fully-sealed construction.

In some aspects, the PCB includes at least one ceramic surface mount capacitor.

In some aspects, the motor is configured to rotate at 75,000 rotations per minute or more.

In some aspects, the motor is configured to rotate at 100,000 rotations per minute or more.

Power tools described herein include a motor, a battery pack, and an inverter electrically connected to the motor and the battery pack. The inverter includes a plurality of wide band gap semiconductor switches and configured to control power supplied by the battery pack to the motor. The plurality of wide band gap semiconductor switches have an energy band gap of about 3 electronvolts (“eV”) or greater.

In some aspects, the motor is configured to act as a heat sink for the inverter.

In some aspects, the power tool includes a heat sink, and the inverter is mounted to the motor via the heat sink.

In some aspects, the power tool includes a heat plate connected to the motor.

Power tools described herein include a motor, a power source, and a printed circuit board (“PCB”) electrically connected to the motor and the power source. The motor is configured to rotate at 75,000 rotations per minute or more. The PCB includes a plurality of wide band gap semiconductor switches configured as an inverter for controlling power supplied by the power source to the motor.

In some aspects, the motor includes a frame, and wherein the PCB is mounted directly to the frame.

In some aspects, the power tool includes a heat sink, and the PCB is mounted to the heat sink and the heat sink is mounted to the motor.

In some aspects, the power tool includes a heat plate connected to the motor, and the heat plate is connected to a heat pipe and the heat pipe is connected to a heat sink.

In some aspects, the PCB includes at least one ceramic surface mount capacitor. In some aspects, the PCB is mounted to the motor.

In some aspects, inverter is a five-level flying capacitor multilevel inverter.

Before any embodiments are explained in detail, it is to be understood that the embodiments are not limited in application to the details of the configuration and arrangement of components set forth in the following description or illustrated in the accompanying drawings. The embodiments are capable of being practiced or of being carried out in various ways. Also, it is to be understood that the phraseology and terminology used herein are for the purpose of description and should not be regarded as limiting. The use of “including,” “comprising,” or “having” and variations thereof are meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings.

In addition, it should be understood that embodiments may include hardware, software, and electronic components or modules that, for purposes of discussion, may be illustrated and described as if the majority of the components were implemented solely in hardware. However, one of ordinary skill in the art, and based on a reading of this detailed description, would recognize that, in at least one embodiment, the electronic-based aspects may be implemented in software (e.g., stored on non-transitory computer-readable medium) executable by one or more processing units, such as a microprocessor and/or application specific integrated circuits (“ASICs”). As such, it should be noted that a plurality of hardware and software-based devices, as well as a plurality of different structural components, may be utilized to implement the embodiments. For example, “servers,” “computing devices,” “controllers,” “processors,” etc., described in the specification can include one or more processing units, one or more computer-readable medium modules, one or more input/output interfaces, and various connections (e.g., a system bus) connecting the components.

Relative terminology, such as, for example, “about,” “approximately,” “substantially,” etc., used in connection with a quantity or condition would be understood by those of ordinary skill to be inclusive of the stated value and has the meaning dictated by the context (e.g., the term includes at least the degree of error associated with the measurement accuracy, tolerances [e.g., manufacturing, assembly, use, etc.] associated with the particular value, etc.). Such terminology should also be considered as disclosing the range defined by the absolute values of the two endpoints. For example, the expression “from about 2 to about 4” also discloses the range “from 2 to 4”. The relative terminology may refer to plus or minus a percentage (e.g., 1%, 5%, 10%, or more) of an indicated value.

It should be understood that although certain drawings illustrate hardware and software located within particular devices, these depictions are for illustrative purposes only. Functionality described herein as being performed by one component may be performed by multiple components in a distributed manner. Likewise, functionality performed by multiple components may be consolidated and performed by a single component. In some embodiments, the illustrated components may be combined or divided into separate software, firmware and/or hardware. For example, instead of being located within and performed by a single electronic processor, logic and processing may be distributed among multiple electronic processors. Regardless of how they are combined or divided, hardware and software components may be located on the same computing device or may be distributed among different computing devices connected by one or more networks or other suitable communication links. Similarly, a component described as performing particular functionality may also perform additional functionality not described herein. For example, a device or structure that is “configured” in a certain way is configured in at least that way but may also be configured in ways that are not explicitly listed.

Other aspects of the embodiments will become apparent by consideration of the detailed description and accompanying drawings.

### BRIEF DESCRIPTION OF THE DRAWINGS

FIG. 1 illustrates a power tool, according to embodiments described here.

FIG. 2 illustrates a control system for the power tool of FIG. 1, according to embodiments described herein.

FIGS. 3A, 3B, and 3C each illustrate an example embodiment of a wide band gap (WBG) inverter, according to embodiments described herein.

FIG. 3D illustrates various components of a PCB configured as a WBG inverter, according to embodiments described herein.

FIG. 3E illustrates a table that includes switching states of a five-level flying capacitor multilevel inverter as depicted in FIG. 3C, according to embodiments described herein.

FIGS. 4A, 4B, and 4C illustrate example layouts of a PCB configured as a WBG inverter, according to embodiments described herein.

FIG. 5 illustrates an example embodiment of a motor that includes a WBG inverter coupled directly to the motor, according to embodiments described herein.

FIG. 6. illustrates an example embodiment that includes a WBG inverter coupled to a motor via a heat sink, according to embodiments described herein.

FIG. 7A illustrates an example embodiment that includes a WBG inverter coupled to a motor via a heat sink that is coupled to a thermal dynamic device, according to embodiments described herein.

FIG. 7B illustrates an example embodiment of the heat sink coupled to the thermal dynamic device.

### DETAILED DESCRIPTION

Embodiments described herein relate to an electrical device, such as a power tool, which includes a motor, a power source, and a printed circuit board (“PCB”) electrically connected to the motor and the power source. The PCB is configured as an inverter controlling the voltage and frequency of power supplied by the power source to the motor. The PCB is mounted to the motor. In some embodiments, the motor comprises a frame, and wherein the PCB is mounted directly to the frame. In some embodiments, the motor is configured to act as a heat sink. In some embodiments, the electrical device further includes a heat sink. In some embodiments, the PCB is mounted to the motor via the heat sink. In some embodiments, the heat sink is employed for thermal dissipation of the PCB. In some embodiments, the heat sink is air cooled and provides additional cooling between the PCB and the motor. In some embodiments, the electrical device further includes a thermal dynamic device. In some embodiments, the heat sink is coupled to the thermal dynamic device. In some embodiments, the thermal dynamic device is heat plate connected to a heat pipe. In some embodiments, the motor, PCB, heat sink, and thermal dynamic device are housed in a sealed construction. In some embodiments, the PCB includes at least one ceramic surface mount capacitor. In some embodiments, the motor is an alternating current (AC) motor. In some embodiments, power source produces a direct current (DC).

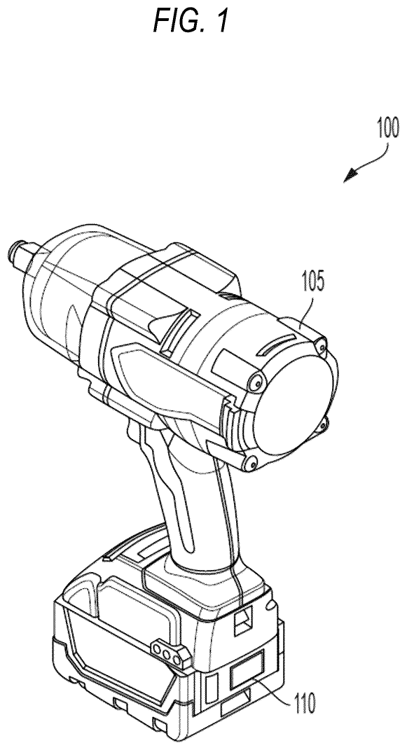

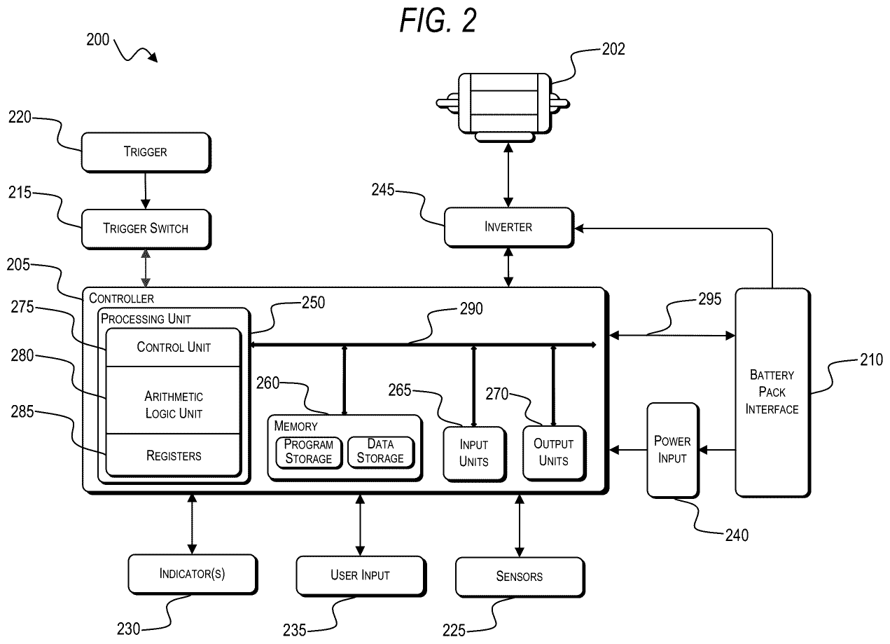

FIG. 1 illustrates a power tool 100. The power tool 100 may be, for example, an impact wrench, a drill, a ratchet, a saw, a hammer drill, an impact driver, a rotary hammer, a grinder, a blower, a trimer, etc. The power tool 100 includes a housing or a motor housing 105 which houses a motor (see FIG. 2) within the power tool 100. The power tool is configured to receive a power source 110 that provides direct current (DC) power to the various components of the power tool 100, including the motor. The power source 110 may be a power tool battery pack that is rechargeable and uses, for instance, lithium ion battery cells.

FIG. 2 illustrates a control system 200 for the power tool 100. The control system 200 includes a controller 205. The controller 205 is electrically and/or communicatively connected to a variety of modules or components of the power tool 100. For example, the illustrated controller 205 is electrically connected to a motor 202, a battery pack interface 210, a trigger switch 215 (connected to a trigger 220), one or more sensors or sensing circuits 225, one or more indicators 230, a user input module 235, a power input module 240, and an inverter or FET switching module 245. The controller 205 includes combinations of hardware and software that are operable to, among other things, control the operation of the power tool 100, monitor the operation of the power tool 100, activate the one or more indicators 230 (e.g., an LED), etc.

The controller 205 includes a plurality of electrical and electronic components that provide power, operational control, and protection to the components and modules within the controller 205 and/or the power tool 100. For example, the controller 205 includes, among other things, a processing unit 250 (e.g., a microprocessor, a microcontroller, an electronic processor, an electronic controller, or another suitable programmable device), a memory 260, input units 265, and output units 270. The processing unit 250 includes, among other things, a control unit 275, an ALU 280, and a plurality of registers 285, and is implemented using a known computer architecture (e.g., a modified Harvard architecture, a von Neumann architecture, etc.). The processing unit 250, the memory 260, the input units 265, and the output units 270, as well as the various modules or circuits connected to the controller 205 are connected by one or more control and/or data buses (e.g., common bus 290). The control and/or data buses are shown generally in FIG. 2 for illustrative purposes.

In some embodiments, the memory 260 is a non-transitory computer readable medium and includes, for example, a program storage area and a data storage area. In some embodiments, the program storage area and the data storage area include combinations of different types of memory, such as a read only memory (ROM), a random access memory (RAM) (e.g., dynamic random access memory (DRAM), synchronous dynamic random access memory (SDRAM), etc.), electronically erasable programmable read-only memory (EEPROM), flash memory, a hard disk, an secure digital (SD) card, or other suitable magnetic, optical, physical, or electronic memory devices. The processing unit 250 is connected to the memory 260 and executes software instructions that are capable of being stored in a RAM of the memory 260 (e.g., during execution), a ROM of the memory 260 (e.g., on a generally permanent basis), or another non-transitory computer readable medium such as another memory or a disc. In some embodiments, software included in the implementation of the power tool 100 is stored in the memory 260 of the controller 205. The software includes, for example, firmware, one or more applications, program data, filters, rules, one or more program modules, and other executable instructions. In some embodiments, the controller 205 is configured to retrieve from the memory 260 and execute, among other things, instructions related to the control processes and methods described herein. In other constructions, the controller 205 includes additional, fewer, or different components.

In some embodiments, the battery pack interface 210 includes a combination of mechanical components (e.g., rails, grooves, latches, etc.) and electrical components (e.g., one or more terminals) configured to and operable for interfacing (e.g., mechanically, electrically, and communicatively connecting) the power tool 100 with a battery pack. For example, power provided by the battery pack 110 to the power tool 100 is provided through the battery pack interface 210 to the power input module 240. In some embodiments, the power input module 240 includes combinations of active and passive components to regulate or control the power received from the battery pack 110 prior to power being provided to the controller 205. In some embodiments, the battery pack interface 210 also supplies power to the inverter 245 to be switched by the inverter to selectively provide power to the motor 202. The battery pack interface 210 also includes, for example, a communication line 295 for provided a communication line or link between the controller 205 and the battery pack 110.

In some embodiments, the inverter 245 is configured on a printed circuit board (“PCB”) that is electrically connected to the motor 202 and the battery pack 110. In some embodiments, the motor 202 is an alternating current (AC) motor. In such embodiments, the inverter 245 is configured to control the voltage and frequency of the power supplied by the battery pack 110 to the motor 202. In some embodiments, the PCB includes logical decision-making devices or gate drivers such as microcontrollers (MCUs), central processing units (CPUs), field programmable gate arrays (FPGAs), etc., which are coupled to power electronic devices such as transistors. In some embodiments, the PCB includes WBG semiconductors to form a WBG inverter. Herein, a “WBG semiconductor” refers to a semiconductor that has an energy band gap that is wider than silicon. Generally, silicon has an energy band gap of about 1.1 electronvolt (eV). WBG semiconductors may have an energy band gap of about 3 eV or greater. However, in some embodiments, the employed WBG semiconductor has an energy band gap that is less than 3 eV. Generally, the wider the energy band gap, the higher the critical field, which means that breakdown voltage may be larger for the same size wide band gap semiconductor formed device, relative to silicon.

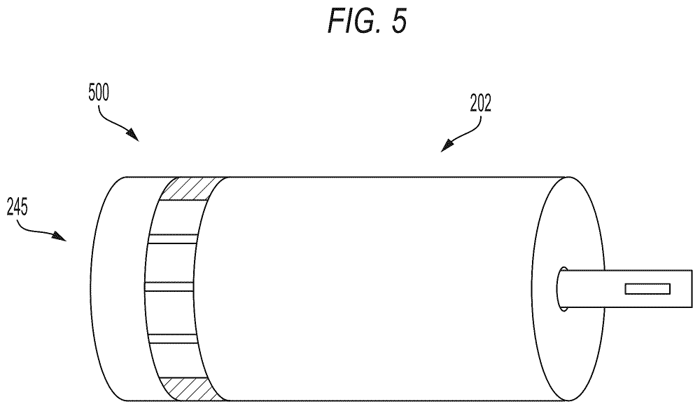

By using WBG semiconductors, the WBG inverter 245 can be mounted to smaller machines due to the smaller size of the semiconductors, the higher frequency of operation enabled by WBG semiconductors, and the higher operating temperatures. In some embodiments, employing the WBG inverter 245 enables higher speed motor operation (e.g., 75,000 to 100,000 revolutions per minute [RPM] or more as opposed to, for example, 30,000 RPM). Moreover, a WBG inverter 245 provides for a smaller size, lower losses, enhanced thermal conductivity, higher operating temperature, etc., relative to inverters formed with silicon-based semiconductors. As such, the WBG inverter 245 can be mounted directly to the motor 202 without incurring much if any penalty (see FIGS. 5-7B). In some embodiments, the PCB includes ceramic surface mount capacitors, which are smaller, can work at higher temperatures, and have higher reliability than, for example, aluminum electrolytic capacitors. The WBG inverter 245 enables increased power for a given motor package or the same power in a smaller motor package.

The indicators 230 include, for example, one or more light-emitting diodes (“LEDs”). In some embodiments, the indicators 230 are configured to display conditions of, or information associated with, the power tool 100. For example, the indicators 230 can be configured to indicate measured electrical characteristics of the power tool 100, the status of the device, etc. The user input module 235 is operably coupled to the controller 205 to, for example, select a forward mode of operation or a reverse mode of operation, a torque and/or speed setting for the power tool 100 (e.g., using torque and/or speed switches), etc. In some embodiments, the user input module 235 includes a combination of digital and analog input or output devices required to achieve a desired level of control for the power tool 100, such as one or more knobs, one or more dials, one or more switches, one or more buttons, etc.

The sensors 225 include one or more current sensors, one or more speed sensors, one or more Hall-effect sensors, one or more temperature sensors, etc. The controller 205 calculates or includes, within memory 260, predetermined operational threshold values and limits for operation of the power tool 100. For example, when a potential thermal failure (e.g., of a FET, the motor 202, etc.) is detected or predicted by the controller 205, power to the motor 202 can be limited or interrupted until the potential for thermal failure is reduced.

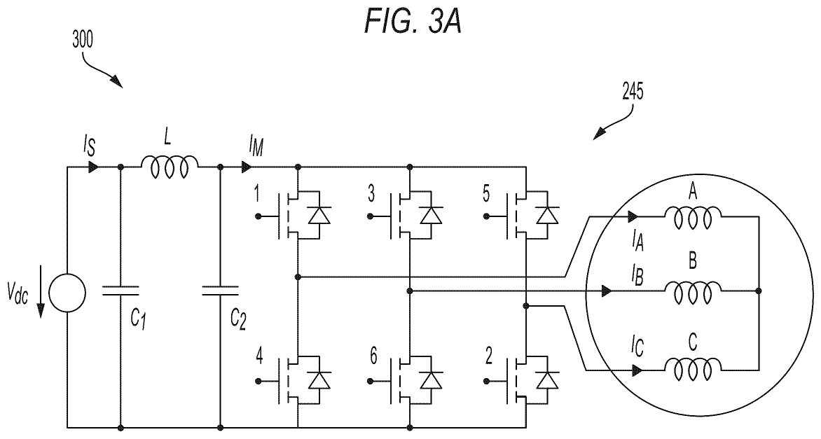

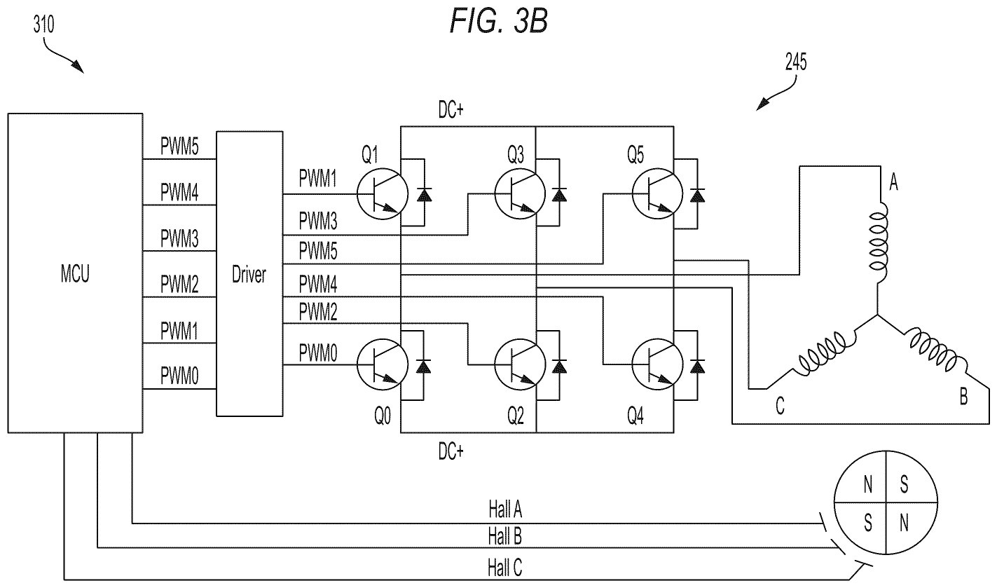

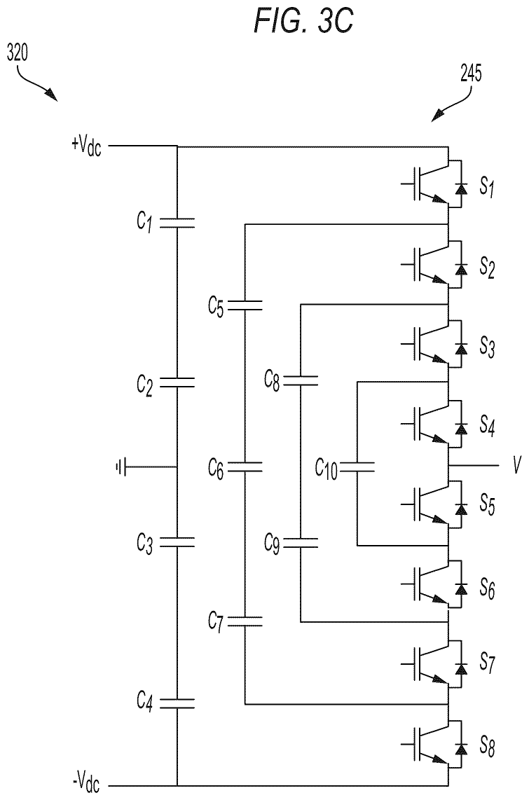

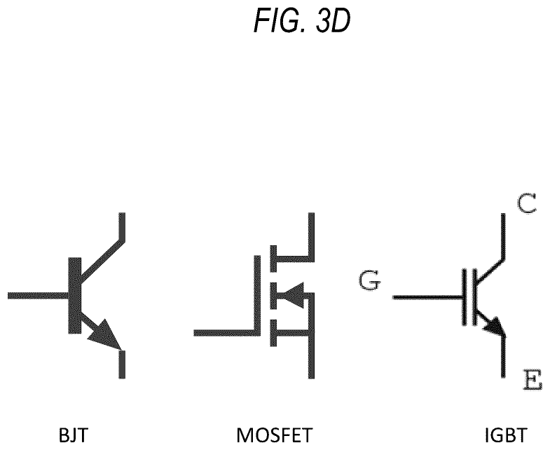

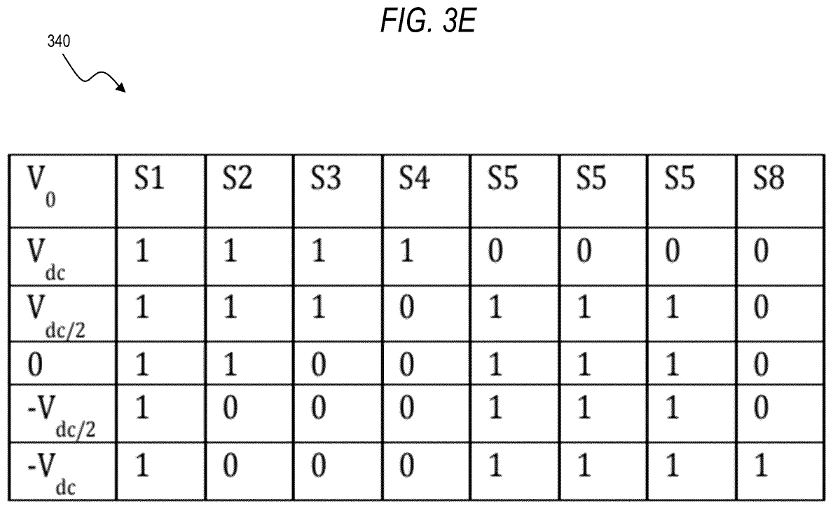

FIGS. 3A, 3B, and 3C each illustrate an example embodiment 300, 310, and 320, respectively, of the WBG inverter 245 for the power tool 100. The example embodiment 310 is implemented with components such as bipolar junction transistors (BJTs), metal-oxide-semiconductor field-effect transistors (MOSFETs), insulated-gate bipolar transistors (IGBTs), etc., which are illustrated in FIG. 3D. The example embodiment 320 is a five-level flying capacitor multilevel inverter, but other types of multi-level inverters could also be used in the power tool 100. FIG. 3E illustrates a table that includes switching state of the five-level flying capacitor multilevel inverter 320.

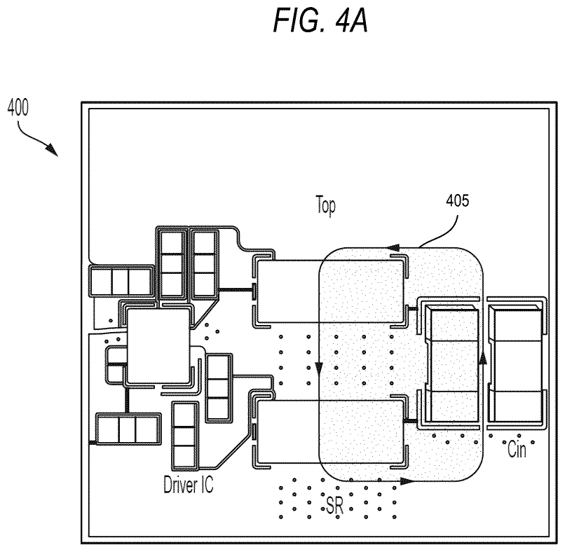

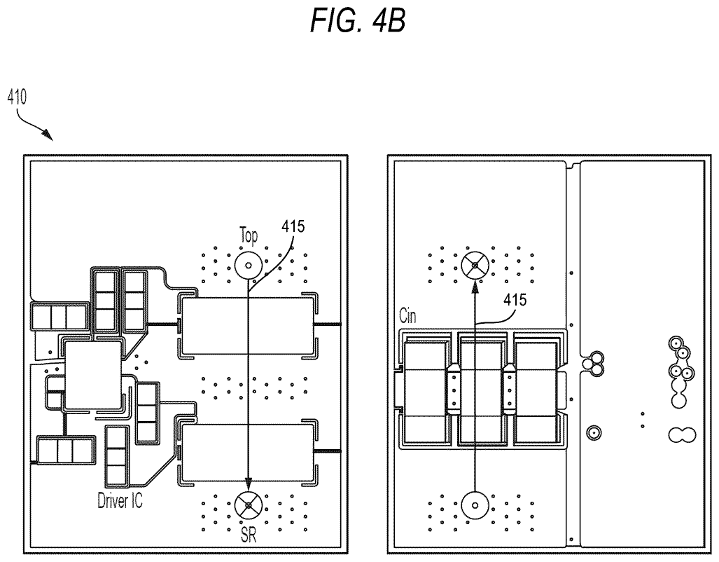

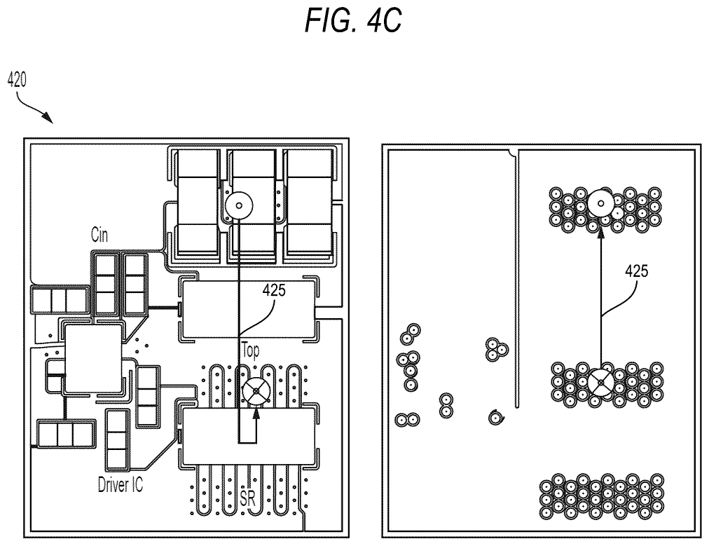

FIGS. 4A, 4B, and 4C illustrate example layouts 400, 410, and 420, respectively, of the PCB configured as the WBG inverter 245. The example layouts 400, 410, and 420 depict power flows to manage the path where the current flows and returns. The example layout 400 is a lateral power loop 405 for a WBG half bridge configuration (i.e., with input capacitors on the same side of the PCB as the power inputs). The power loop 405 generates a magnetic field that induces a current in a shield layer of the PCB, and that flows in the opposite direction to the power loop 405. The current in the shield layer generates a magnetic field to counteract the original power loop's magnetic field, which results is a cancellation of magnetic fields. The shield layer is positioned in close proximity to the power loop 405 (e.g., as a second layer of the PCB) to minimize power loop inductance in the lateral power loop configuration.

The example layout 410 is a vertical power loop 415 for a WBG half bridge configuration (i.e., with input capacitors on an opposite side of the PCB as the power inputs). As the thickness of the PCB is reduced, the area of the power loop 415 also decreases. Current flowing in opposing directions on the top and bottom layers of the PCB provide magnetic self-cancellation.

The example layout 420 is an optimized power loop 425 for WBG half bridge configuration (i.e., with input capacitors on the same side of the PCB as the power inputs). The optimized power loop 425 uses a first inner layer (right in FIG. 4C) as a power loop return path. The return path is located directly beneath the top layer of the PCB's power loop 425 (left in FIG. 4C). Such a positioning achieves the smallest physical loop area while also benefitting from magnetic field self-cancellation.

FIG. 5 illustrates an example embodiment 500 that includes the WBG inverter 245 coupled directly to the motor 202 (e.g., to the frame of the motor 202). In the depicted embodiment, the thermal properties of the motor 202 act as a heat sink for the WBG inverter 245. Any of the layouts 400, 410, 420 can be used when implementing the WBG inverter 245.

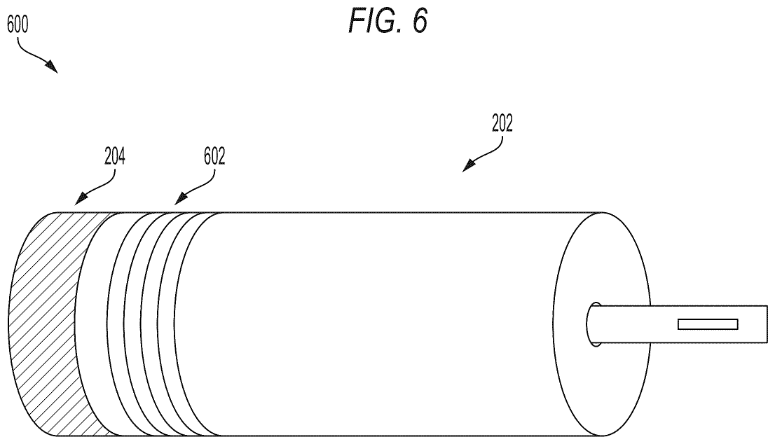

FIG. 6. illustrates an example embodiment 600 that includes the WBG inverter 245 coupled to the motor 202 via a heat sink 602. The inverter 245 is mounted to the heat sink 602, and the heat sink 602 is mounted to the motor 202. In such embodiments, the heat sink 602 is employed for thermal dissipation of the WBG inverter 245. In some embodiments, the heat sink 602 is air cooled (e.g., by a fan) and provides additional cooling between the WBG inverter 245 and the motor 202. Any of the layouts 400, 410, 420 can be used when implementing the WBG inverter 245.

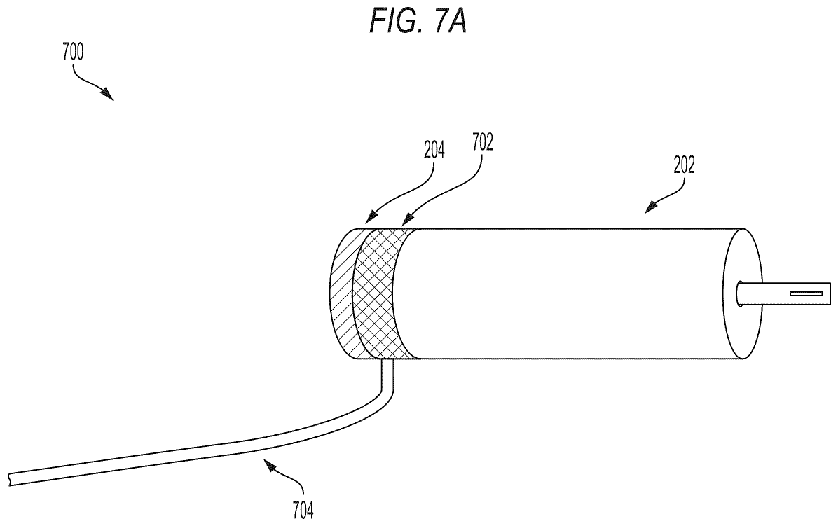

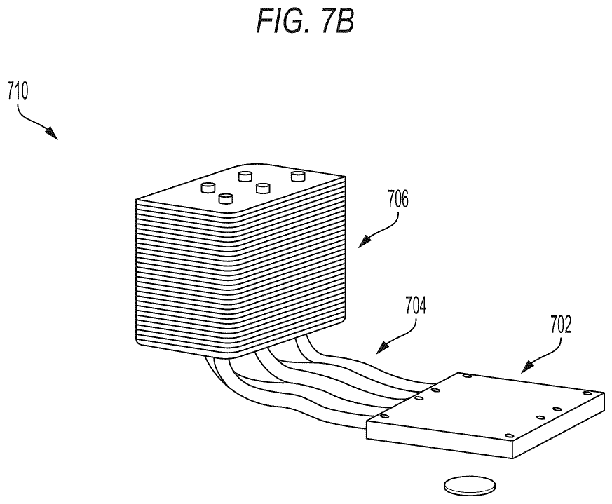

FIG. 7A illustrates an example embodiment 700 that includes the WBG inverter 245 coupled to the motor 202 via a heat plate 702 that is coupled to a heat pipe or thermal dynamic device 704. The example embodiment 700 may be employed, for example, in demanding applications where forced air cooling is not available, in fully-sealed constructions (e.g., no openings for improved ingress protection), or in submersible applications. Any of the layouts 400, 410, 420 can be used when implementing the WBG inverter 245.

FIG. 7B illustrates an example embodiment 710 of the heat plate 702 coupled to the thermal dynamic device 704. In the depicted embodiment, the heat plate 702 is thermally connected to a heat sink 706 by the heat pipe 704.

In each of the example embodiments 500, 600, and 700, the WBG inverter 245 is coupled to the battery pack 110 as depicted in FIG. 2. In some embodiments, the depicted WBG inverter 245 (the PCB) is fastened to the motor 202, the heat sink 602, or the heat plate 702.

Thus, embodiments described herein provide, among other things, a power tool including a printed circuit board with embedded busbars. Various features and advantages are set forth in the following claims.

What is claimed is:

1. A power tool comprising:
a motor;
a power source; and
a printed circuit board (“PCB”) electrically connected to the motor and the power source, the PCB mounted to the motor, the PCB including a plurality of wide band gap semiconductor switches configured as an inverter for controlling power supplied by the power source to the motor.

2. The power tool of claim 1, wherein the motor includes a frame, and wherein the PCB is mounted directly to the frame.

3. The power tool of claim 2, wherein the motor is configured to act as a heat sink for the inverter.

4. The power tool of claim 1, further comprising a heat sink, wherein the PCB is mounted to the heat sink and the heat sink is mounted to the motor.

5. The power tool of claim 4, wherein the heat sink is air cooled.

6. The power tool of claim 4, further comprising input capacitors, wherein the input capacitors and the inverter are mounted on the same side of the PCB.

7. The power tool of claim 1, further comprising a heat plate connected to the motor.

8. The power tool of claim 7, wherein the heat plate is connected to a heat pipe and the heat pipe is connected to a heat sink.

9. The power tool of claim 8, wherein the motor, the PCB, and the heat plate are housed in a fully-sealed construction.

10. The power tool of claim 1, wherein the PCB includes at least one ceramic surface mount capacitor.

11. The power tool of claim 1, wherein the motor is configured to rotate at 75,000 rotations per minute or more.

12. The power tool of claim 11, wherein the motor is configured to rotate at 100,000 rotations per minute or more.

13. A power tool comprising:
a motor;
a battery pack interface configured to receive a battery pack;
an inverter electrically connected to the motor and the battery pack interface, the inverter including a plurality of wide band gap semiconductor switches, the inverter configured to control power supplied by the battery pack to the motor,
wherein the plurality of wide band gap semiconductor switches have an energy band gap of about 3 electronvolts (“eV”) or greater.

14. The power tool of claim 13, wherein the motor is configured to act as a heat sink for the inverter.

15. The power tool of claim 13, further comprising:
a heat sink,
wherein the inverter is mounted to the motor via the heat sink.

16. The power tool of claim 13, further comprising a heat plate connected to the motor.

17. A power tool comprising:
a motor configured to rotate at 75,000 rotations per minute or more;
a power source;
a printed circuit board (“PCB”) electrically connected to the motor and the power source, the PCB including:
a plurality of wide band gap semiconductor switches configured as an inverter for controlling power supplied by the power source to the motor.

18. The power tool of claim 17, wherein the motor includes a frame, and wherein the PCB is mounted directly to the frame.

19. The power tool of claim 17, further comprising a heat sink, wherein the PCB is mounted to the heat sink and the heat sink is mounted to the motor.

20. The power tool of claim 17, further comprising a heat plate connected to the motor, wherein
the heat plate is connected to a heat pipe and the heat pipe is connected to a heat sink.

21. The power tool of claim 17, wherein the PCB includes at least one ceramic surface mount capacitor.

22. The power tool of claim 17, wherein the PCB is mounted to the motor.

23. The power tool of claim 17, wherein the inverter is a five-level flying capacitor multilevel inverter.
